(19) United States
(12) Patent Application Publication
(10) Pub. No.: US 2009/0295412 A1
(43) Pub. Date: Dec. 3, 2009

(54) Occupant Detector with Electronic Interference Compensation

(75) Inventor: Dennis P. Griffin, Noblesville, IN (US)

Correspondence Address: DELPHI TECHNOLOGIES, INC., M/C 480-410-202, PO BOX 5052, TROY, MI, 48007, US

(73) Assignee: DELPHI TECHNOLOGIES, INC., Troy, MI (US)

(21) Appl. No.: 12/434,079

(22) Filed: May 1, 2009

Related U.S. Application Data
(63) Continuation-in-part of application No. 12/150,439, filed on Apr. 28, 2008.
(60) Provisional application No. 61/126,120, filed on May 1, 2008.

(51) Int. Cl. G01R 27/26

(52) U.S. Cl. 324/681

(57) ABSTRACT

A occupant detection system includes an electronic device in communication with a sensor. The system detects an occupant by way of measuring an impedance of an electric field emitted by the sensor. The electronic device is configured to acquire data values from an output signal of the sensor, and reduce the effect of transient electrical interference on the acquired data values and adapt for sustained electrical interference on the acquired data values. A method includes acquiring a new data value, determining whether the new data value represents transient interference, and capturing the new data value if the new data value is free of transient interference and rejecting the new data value if the new data value represents transient interference.

### CROSS-REFERENCE TO RELATED APPLICATIONS

This application is a continuation-in-part of pending U.S. patent application Ser. No. 12/150,439, filed on May 28, 2008, the contents of which are fully incorporated herein by reference. In addition, this application claims priority to U.S. Provisional Application Ser. No. 61/126,120, filed on May 1, 2008.

### TECHNICAL FIELD OF INVENTION

The invention relates detecting an occupant in a vehicle. More particularly, the invention relates to reducing electrical interference interfering with detecting an occupant.

### BACKGROUND

Occupant detection systems have the ability to determine the presence and/or characteristics of an occupant at a specific location. However, environmental conditions, such as electronic interference, may interfere with the occupant detection system's readings. While airbags have been known to provide additional safety to adult and larger children traveling in vehicles, it is not always ideal to deploy the airbag even though a person is detected. The determination of the presence and/or characteristics of an occupant may be used to enabling or disabling an airbag system. For this reason, it is desirable that the occupant detection system is not affected by electronic interference. For instance, electronic noise from electrostatic discharge or a cell phone may cause some occupants to be mischaracterized as adults, meaning the airbag would be enabled even though an infant seat occupied the seat. Accordingly, an occupant detection system is needed that compensates for electronic noise.

### BRIEF SUMMARY

Described herein is an occupant detection system including a sensor disposed in a seat, and an electronic device in communication with the sensor to receive a signal for the sensor, said electronic device configured to determine an impedance value indicative of a load based upon the signal, detect an interference signal, and determine an occupant based upon the impedance value and the interference signal. The interference signal may be indicative of sustained interference. The electronic device may be configured to process a first signal having a first frequency from the sensor, determine if the first signal is indicative of a sustained interference, if a sustained interference is determined, processing a second signal having a second frequency from the sensor, and determine the impedance value based upon the second signal. The interference signal may also be indicative of a transient interference.

The electronic device may be further configured to process a series of signals from the sensor, for each signal, determine whether the signal is indicative of transient interference, and determine a sustained interference if a number of signals in the series indicating transient interference is greater than a threshold. The electronic device may also be further configured to determine a first impedance value for a first signal at a first frequency and a second impedance value for a second signal at a second frequency, to compare the first impedance value to the second impedance value, and determine an occupant based upon the first impedance value if a difference between the first impedance value and the second impedance value is below a threshold. The electronic device may be also configured to process a series of signals from the sensor, for each signal, determine an impedance value, to determine an occupant if the impedance value is the same for a number of signals in the series and the number exceeds a threshold.

The electronic device may also have an interference signal detection circuit and an impedance detection circuit, wherein the interference signal detection circuit is enabled and the impedance detection circuit is disabled during a listen mode to detect transient interference, and wherein the interference signal detection circuit and the impedance detection circuit are enabled during a receive mode. The electronic device may also be configured to enable or disable an airbag system of a vehicle based upon the determination of an occupant.

Also described herein is a method of detecting an occupant including the steps of transmitting a signal at a first frequency, detecting an impedance value indicative of a load based upon a received signal in response to the transmitted signal, detecting an interference signal at the first frequency, and determining an occupant based upon the impedance and the interference signal. The method may also include steps to perform actions enabled by the description of the system above.

### BRIEF DESCRIPTION OF THE DRAWINGS

FIG. 1 is a block diagram of an exemplary system;

FIG. 2 is a flowchart of an exemplary heuristic for acquiring and verifying data;

FIG. 3 is a flowchart of the data acquisition phase of the exemplary system heuristic having a Listen and a Receive mode;

FIG. 4A is a flowchart of an exemplary system response as determined by a system control module during a frequency sweep while the sensor is in the Listen mode;

FIG. 4B is a flowchart of an exemplary system response as determined by a system control module during a frequency sweep to suppress transients; and

FIG. 5 is a partial side view of an exemplary system disposed in a vehicle for vehicle occupant detection.

### DETAILED DESCRIPTION

An occupant detection system may be used in a vehicle to detect an occupant or other object in a seat independent of electrical noise or other interference. The system includes a sensor that monitors a condition and outputs a signal representing the condition to an electronic device. The condition may include electric field impedance value near the sensor, or electronic interference received by the sensor. The electronic device interprets a signal from the sensor, and reduces the effect of electronic interference on the impedance value received from the sensor. The electronic device may be any set of electronic components effective to detect the impedance value and the electronic interference. For example, the system may be used in a vehicle where various environmental conditions or interference from other devices may affect the operation of the system and/or various vehicle components. The electronic device, in this exemplary approach, reduces the effect of the electronic interference on the impedance value received from the sensor.

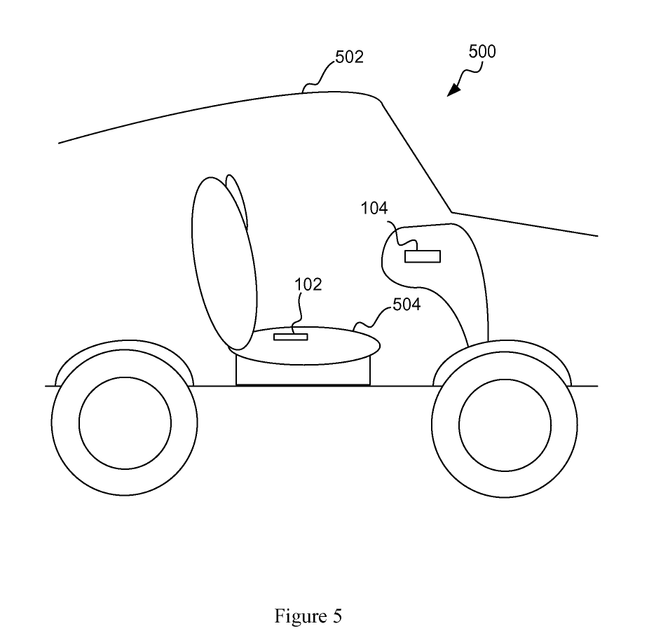

FIG. 5 is a cut-away view of a vehicle 500 having a seat 504, a sensor 102 disposed within the seat, and an electronic device 104 within the interior 502 of the vehicle. The seat is for supporting an occupant (not shown). The occupant may be an individual person of any size, either sitting on the seat or may be an infant or child sitting in a child seat, where the child seat is secured to the seat with a seat belt (not shown) or some other means of secure attachment. The sensor 102 communicates with electronic device 104, preferably via a wire (not shown), or alternately via some wireless communication method such as Blue Tooth. Sensor 102 may be a sensor assembly containing electronics, or simply a heating element within the seat that is also used for heating the seat. similar to a seat heating element, but could also be formed using foil or other electrically conductive element. Electronic device 104 provides a signal to an airbag deployment system (not shown) for determining if the airbag should be deployed. A description of a suitable occupant detection system may be found in U.S. patent application Ser. No. 12/150,439.

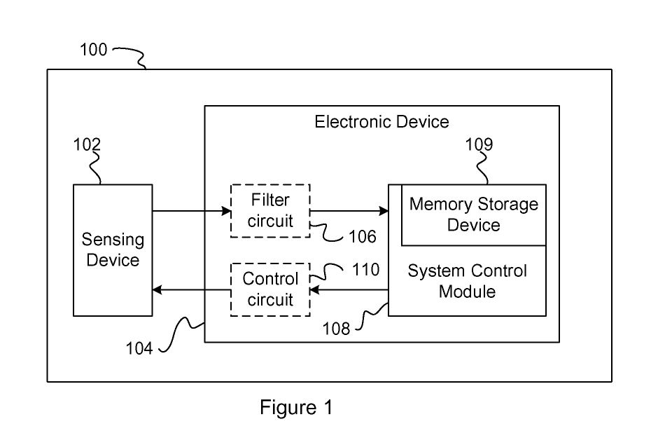

FIG. 1 is a block diagram of an exemplary system 100. The system 100 includes a sensor 102 in communication with an electronic device 104 that includes a system control module 108. In one exemplary approach, the system control module 108 monitors and digitally filters the signal received from the sensor 102 to reduce or eliminate errors caused by electrical interference. The system control module 108 may include a control circuit 110 to communicate with and control the sensor 102, and/or a filter circuit 106 for protecting the system control module 108 from damage due to the electrical interference. Both the filter circuit 106 and the control circuit 110 may be a passive or active analog circuit, or may use digital filtering performed by an electronic component other than system control module 108. In this way, the filter circuit 106 protects system control module 108 from damage due to electrical interference. Moreover, although shown as wired communication, it is appreciated that the various components of the system 100 may alternatively communicate wirelessly or via a combination of wireless and wired communication.

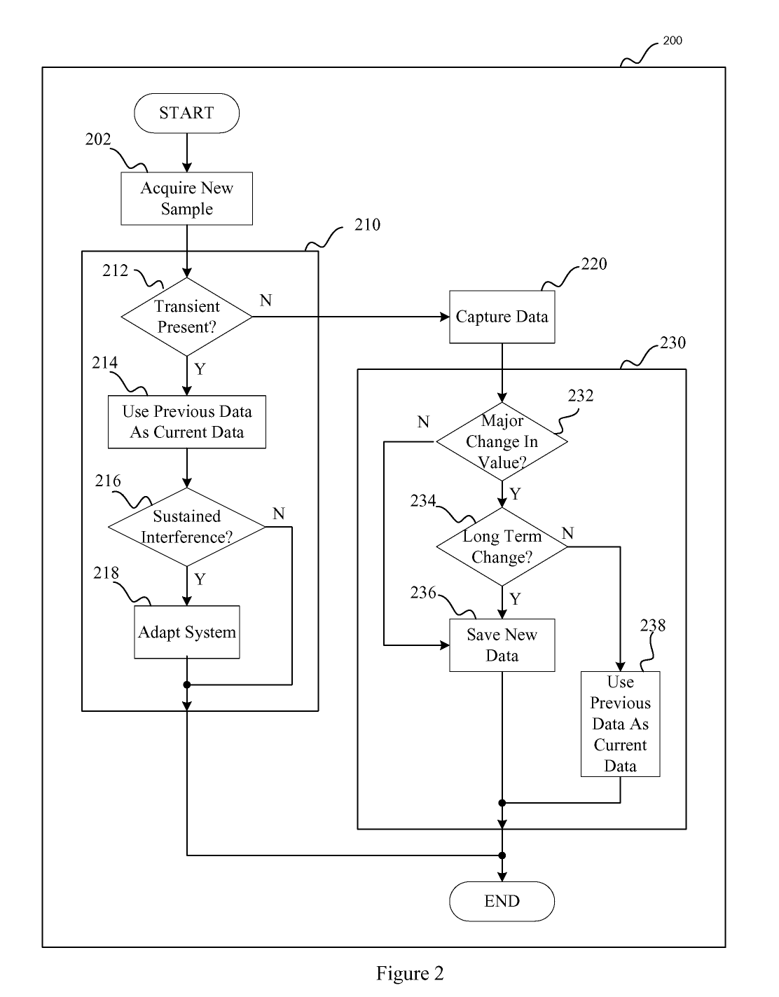

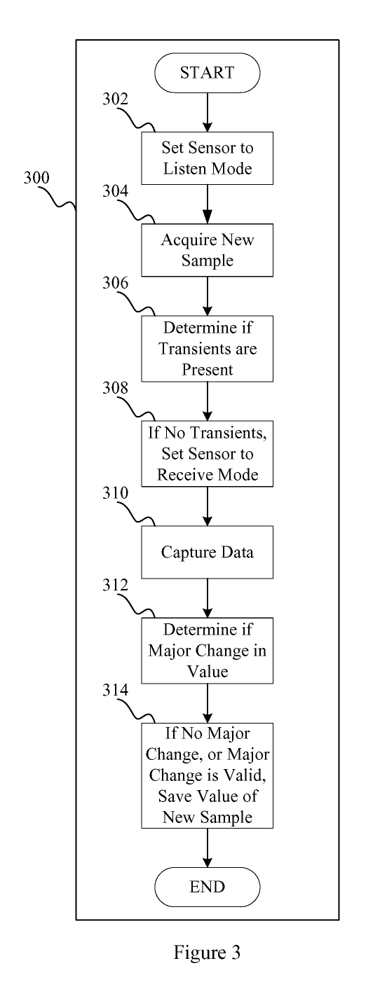

As discussed in greater detail below, the system control module 108 uses a detection heuristic to determine that interference exists, what type of interference it is, and how to adapt to the interference, if necessary. As used herein, detection heuristic or heuristic includes any method or machine capable of accomplishing or performing one or a sequence of: steps or functions or tasks, such as illustrated in FIG. 2 or 3. Specifically, the system control module 108 includes a memory storage device 109 storing instructions for executing a heuristic to recognize transient interference and sustained interference electrically superimposed over the sensor output signal. For example, the heuristic may include instructions that digitally filter the signal from the sensor 102 received by electronic device 104 and interpreted by system control module 108. The heuristic is not limited to operation within system control module 108. For example, in one exemplary approach, the heuristic may alternatively be firmware or software within sensor 102.

Transient interference may materially affect the functionality of the system, but its duration is short enough that it can be ignored or isolated to minimize its affect on the input data. Sustained interference is not temporally short enough to be ignored or isolated by the system and is, therefore, significant enough to materially affect the functionality of the system. Transient electrical interference may be from, for example, electromagnetic interference (EMI), electrostatic discharge (ESD), cross-talk (coupling) between electrical lines, switching noise when the sensor 102 or the device it is sensing is turned on or off, or any other source of transient disturbance. By its nature transient electrical interference has a generally very short duration when compared to the reaction time of the system 100. If the system 100 is capable of detecting the presence of transient interference, it may ignore transient interference until it passes. Sustained electrical interference may be from nearby constantly-operating motors, RF or cellular towers, and many other sources of sustained disturbance. By its nature sustained electrical interference is of generally longer duration as compared to the reaction time of the system 100 and would therefore materially affect the accuracy of the information received. The system 100 thus seeks to recognize sustained interference from transient interference and adapt appropriately if necessary.

In one exemplary approach, the system control module 108 may be a computing device that may include software applications tangibly embodied as a set of computer-executable instructions on a computer readable medium within the computing device. The computing device may be any one of a number of computing devices, such as a personal computer, handheld computing device, cellular telephone, embedded microprocessor, etc. Computing devices may employ any of a number of computer operating systems, including, but not limited to, known versions and/or varieties of the Microsoft Windows® operating system, the Unix operating system (e.g., the Solaris® operating system distributed by Sun Microsystems of Menlo Park, Calif.), the AIX UNIX operating system distributed by International Business Machines of Armonk, N.Y., and the Linux operating system.

Computing devices generally each include instructions executable by one or more devices such as those listed above. Computer-executable instructions may be compiled or interpreted from computer programs created using a variety of programming languages and/or technologies, including, without limitation, and either alone or in combination, Java™, C, C++, Visual Basic, Java Script, Perl, etc. In general, a processor (e.g., a microprocessor) receives instructions, e.g., from a memory, a computer-readable medium, etc., and executes these instructions, thereby performing one or more processes, including one or more of the processes described herein. Such instructions and other data may be stored and transmitted using a variety of known computer-readable media.

A computer-readable media includes any medium that participates in providing data (e.g., instructions), which may be read by a computer. Such a medium may take many forms, including, but not limited to, non-volatile media, volatile media, and transmission media. Non-volatile media include, for example, optical or magnetic disks and other persistent memory. Volatile media include dynamic random access memory (DRAM), which typically constitutes a main memory. Transmission media include coaxial cables, copper wire and fiber optics, including the wires that comprise a system bus coupled to the processor. Transmission media may include or convey acoustic waves, light waves and electromagnetic emissions, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, a carrier wave as described hereinafter, or any other medium from which a computer can read.

The embodiment of the system 100 shown in FIG. 1 is exemplary only and not limited to the embodiment illustrated. For example, the system control module 108, or other components, may be physically separate from electronic device 104. Furthermore, electronic device 104 is not limited to electrically interfacing with sensor 102 alone, but may interface with many other devices and systems and provide control for many other devices and systems. For example, the electronic device 104 may interface with various vehicle systems, such as an airbag system. However, application of the system 100 need not be limited to vehicle or automotive embodiments.

FIG. 2 is an exemplary flowchart of the heuristic 200 that may operate on system control module 108, and may be repeated as necessary to acquire an appropriate amount of data. Acquisition of data may be from one or more sensors 102, and previous and present data values, along with appropriate counters, may be stored for use in a later iteration of the heuristic, or could be used to compare the outputs of different sensors 102 to each other. Furthermore, the heuristic counters and thresholds may be different values during different iterations.

The heuristic 200 includes a step 202 of acquiring a data sample by, for example, selectively sampling the sensor 102 output signal with an electronic circuit that translates the electrical signal into a form recognizable by system control module 108. A recognizable form may be, e.g., a binary number representing the actual value of the electrical signal within a given resolution, or may be a representation, e.g. a “flag”, indicating that the electrical signal value was either higher or lower than a predetermined voltage or current threshold. The heuristic 200 further includes a step 210 of determining whether interference exists within the system 100. If no interference exists, the heuristic 200 includes a step 230 of determining if the data sample received represents a value for the sensor 102 output signal for use by the system control module 108. Step 230 may be carried out by steps 232-238, which are described in more detail below. Moreover, optional step 220, described further below, allows for the heuristic 200 to acquire one data sample from which to detect electrical interference and a second data sample from which to detect valid data.

Steps 212-218 may be used to carry out step 210. Specifically, the heuristic 200 includes a step 212 of determining whether transient electrical interference is present. Detection of transient interference may be accomplished by, for example, comparing the binary representation of the sensor 102 output signal to a threshold level, or by recognizing whether or not the indication “flag” is set. Short transient electrical interference can be ignored and the uncorrupted previous data may continue to be used for the relatively short duration of the transient interference, because it has no long-term effect upon the system. Therefore, if transient interference is detected at step 212, the acquired data sample is rejected and a previously-acquired data sample is used as the present data sample, as indicated by step 214. Moreover, the previous data sample may be filtered before being designated as the present data sample.

However, sustained electrical interference may cause the data received from the sensor 102 output signal to be unusable within the system 100 because no reliable data is received. If so, the heuristic 200 includes a step 216 of determining if the interference is sustained by, for example, counting of the number of times that a data value representing transient interference has been detected and determining whether that count exceeds a predetermined threshold. To detect sustained interference, the heuristic 200 may be performed at least a number of times equal to the threshold number of detected transient data values used in determining the existence of sustained interference. If sustained interference is not detected at step 216, the heuristic 200 ends. If sustained interference is detected at step 216, the heuristic 200 may further includes a step 218 of adapting the system 100 to prevent the sustained interference from further affecting the system 100. In other words, the system 100 is adapted in a way such that the electromagnetic interference no longer appreciably affects the system and the data is determined to be reliable. In one exemplary approach, the system control module 108 may adapt the system 100 by setting the sensor 102 to an operating frequency, and measuring the sensor 102 output signal as the sensor 102 reacts to system 100 conditions. When sustained electrical interference is detected, the system control module 108 sets the sensor 102 to a different operating frequency, which effectively adapts the system 100 because electrical interference typically exists only within a narrow frequency band and not across a wide range of frequencies at one time.

If no transient interference is detected, the heuristic 200 includes an optional step 220 of capturing a new data sample, or alternatively, simply using the existing data acquired in step 202 for the remainder of the steps in heuristic 200. Capturing the data value may include essentially the same process as acquiring the data sample, but may also involve different electronic circuits or software than those used for acquiring a data sample. Once the data is captured at step 230, the heuristic includes a step 230 of determining if there has been a change in the output of sensor 102 which represents information that system 100 wants to keep for use in a system control function. Step 230 generally saves the data sample acquired in step 202 or the data value captured in step 220. However, if the data represents a major change in the output signal of sensor 102, heuristic 200 includes steps 232-238 to determine if the signal is stable before saving the new acquired data or captured data value as the current data value. Specifically, the heuristic 200 includes a step 232 of determining if there has been a major change in the output signal of sensor 102. Detection of a major change may be determined by subtracting the present data value (i.e., either the acquired data sample or the captured data value) from the previous data value, and comparing the magnitude of the difference to a threshold. The threshold is generally much lower than the threshold used to determine if transient interference is present as described above with respect to step 212. If the difference between the present and previous data values does not exceed the threshold, then no major change in value has been detected and the data value may be filtered and is saved as the current data value in step 236. However, if the difference between the present and previous data values does exceed the threshold, then a major change has been detected, and heuristic 200 includes a step 234 of determining if the major change was a long term change, i.e. the new acquired data sample or captured data value actually represents a stable sensor 102 output signal. In one exemplary approach, a long term change may be determined by counting the number of times step 234 is executed, and determining whether that number exceeds a threshold. However, if the count of the number of times exemplary heuristic 200 reaches step 234 does not exceed the threshold, then heuristic 200 saves the previous data sample value as the current data value in step 238. The heuristic 200 ends after either step 216, 218, 236 or 238.

FIG. 3 illustrates an exemplary heuristic 300 in which the sensor 102 operates in at least two modes: a listen mode and a receive mode. The listen mode may be implemented by disabling the optional control circuit 110, and the receive mode may be implemented by enabling the optional control circuit 110. The heuristic 300 includes a step 302 of setting the sensor 102 to the listen mode prior to a step 304 of acquiring the new sample data. If no transient electrical interference is detected on the acquired data sample at step 306, the sensor 102 is then set to the receive mode in step 308, and a sample of the signal is captured as a data value in step 310. Then, heuristic 300 includes a step 312 of determining whether there was a major change in the data value, and if yes, includes a step 314 of determining if the data value represents a valid signal level. If there is no major change or the major change represents a valid signal level, the captured data value is saved as the current data value in step 314, and heuristic 300 ends. It is appreciated that heuristics 200 and 300 as illustrated in the flowcharts of FIGS. 2 and 3 are exemplary, and not limited to what is shown and/or described.

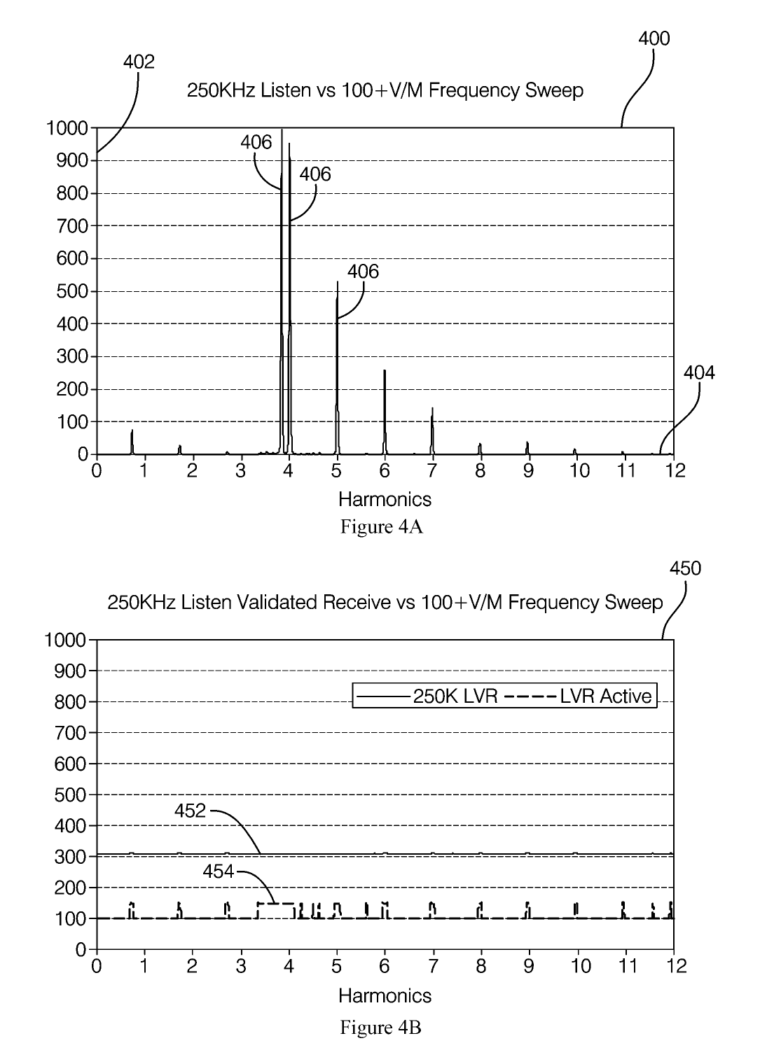

The embodiment of heuristic 300 shown in FIG. 3 was employed in one system in which a sensor 102 was operated at a frequency of 250 kHz. FIGS. 4A and 4B illustrate the system response without and with heuristic 300 operating, respectively.

FIG. 4A illustrates the system without heuristic 300 operating. The graph 400 shows the frequency response of the system when the system was subjected to an electromagnetic test sweep that simulates an environment of strong electromagnetic interference. The test sweep may be performed in an isolated enclosure in order to prevent outside electromagnetic signals from affecting the test results. The test sweep involves applying a strong electromagnetic field to the electronic device 104 at each of a sequence of different frequencies, and measuring the system response at each of the frequencies. In FIG. 4A, the system response recorded was the magnitude of the electrical signal present at the electronic device 104 during the test sweep as interpreted by the system control module 108.

The Y-axis 402 of the graph 400 represents the magnitude of the signal. The X-axis 404 of the graph 400 represents the frequencies of the test sweep. The X-axis 404 is numbered according to multiples of the harmonics of the sensor 102 operating frequency, e.g. “4” on X-axis 404 refers to a frequency four times that of the operating frequency (i.e. four times 250 kHz, equal to 1 MHz). The sensor 102 output signal generally stays at approximately zero during the test sweep. However, as can be seen in graph 400, the signal magnitude reaches substantially greater values than zero at many harmonics of the operating frequency, as documented by “spikes” on graph 400 such as the ones labeled 406. These spikes 406 represent the sensor 102 response to the strong electromagnetic field at those frequencies, illustrating one example of electrical interference that heuristic 300 is intended to detect and accommodate. The spikes can introduce errors into the system 100.

FIG. 4B is a graph 450 of the frequency response of the same system as described in FIG. 4A, wherein parts of heuristic 300, specifically the transient detection test and the stability test (major change test), were operating. The system was exposed to the same kind of frequency sweep as was used to make graph 400 in FIG. 4A. The X- and Y-axis of graph 450 represent frequency and signal level, respectively, as they did in graph 400. Graph 450 shows the result of using heuristic 300 within the system. Graph 450, line 452 represents the signal magnitude, as interpreted by system control module 108 and then filtered using the transient detection test and the stability test. The filtered signal magnitude remains substantially zero. Graph 450, line 454 indicates at which frequencies the heuristic was actively reacting to transient electrical interference. The result of using heuristic 300 is that substantially all of the electromagnetic interference is rejected by the system, such that the electromagnetic interference is not allowed to introduce significant error into the system. In other words, as can be seen by comparing graphs 400 and 450, the spikes 406, representing transient interference on graph 400 that existed at the harmonics of the operating frequency, were detected and effectively eliminated as seen on line 452.

Under normal conditions and without interference, sensor 102 responds well to the presence and/or size of the object or occupant. However, external interference from, for example, RF and EMI sources can interference with the normal operation of the sensor. If the external signal happens to be a harmonic of the operating frequency, the interference can result in erroneous data. Therefore, the electrical signal is sampled and processed by the electronic device 104, and specifically, the system control module 108 as described above. In one exemplary approach, the electronic device 104 uses the heuristics 200, 300 previously described to reduce or eliminate interference and enable the airbag system and/or other automotive systems independent of the interference. However, it is appreciated that the system 100 may be used to enable other systems independent of noise.

Reference in the specification to “one example,” “an example,” “one embodiment,” or “an embodiment” means that a particular feature, structure, or characteristic described in connection with the example is included in at least one example. The phrase “in one example” in various places in the specification does not necessarily refer to the same example each time it appears.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claimed invention.

Accordingly, it is to be understood that the above description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

All terms used in the claims are intended to be given their broadest reasonable constructions and their ordinary meanings as understood by those skilled in the art unless an explicit indication to the contrary in made herein. In particular, use of the singular articles such as “a,” “the,” “said,” etc. should be read to recite one or more of the indicated elements unless a claim recites an explicit limitation to the contrary.

What is claimed is:

1. An occupant detection system comprising:
a sensor disposed in a seat; and
an electronic device in communication with the sensor, said electronic device configured to determine an impedance value indicative of a load based upon the signal, detect an interference signal, and determine an occupant based upon the impedance value and the interference signal.

2. An occupant detection system as set forth in claim 1, wherein the interference signal is indicative of sustained interference.

3. An occupant detection system as set forth in claim 2, wherein the electronic device is configured to
process a first signal having a first frequency from the sensor;
determine if the first signal is indicative of a sustained interference;
if a sustained interference is determined, processing a second signal having a second frequency from the sensor; and
determine the impedance value based upon the second signal.

4. An occupant detection system as set forth in claim 2, wherein the interference signal is indicative of transient interference.

5. An occupant detection system as set forth in claim 4, wherein the electronic device is configured to
process a series of signals from the sensor;
for each signal, determine whether the signal is indicative of transient interference; and
determine a sustained interference if a number of signals in the series indicating transient interference is greater than a threshold.

6. An occupant detection system as set forth in claim 1, wherein the electronic device is configured to determine a first impedance value for a first signal at a first frequency and a second impedance value for a second signal at a second frequency, to compare the first impedance value to the second impedance value, and determining an occupant based upon the first impedance value if a difference between the first impedance value and the second impedance value is below a threshold.

7. An occupant detection system as set forth in claim 1, wherein the electronic device is configured to
process a series of signals from the sensor;
for each signal, determine an impedance value; and
to determine an occupant if the impedance value is the same for a number of signals in the series and the number exceeds a threshold.

8. An occupant detection system as set forth in claim 1, wherein the electronic device has an interference signal detection circuit and an impedance detection circuit, wherein the interference signal detection circuit is enabled and the impedance detection circuit is disabled during a listen mode to detect transient interference, and wherein the interference signal detection circuit and the impedance detection circuit are enabled during a receive mode.

9. An occupant detection system as set forth in claim 1, wherein the electronic device is configured to enable or disable an airbag system of a vehicle based upon the determination of an occupant.

10. A method of detecting an occupant comprising:
transmitting a signal at a first frequency,
detecting an impedance value indicative of a load based upon a received signal in response to the transmitted signal;
detecting an interference signal at the first frequency; and
determining an occupant based upon the impedance and the interference signal.

11. A method of claim 10, wherein the interference signal is indicative of sustained interference.

12. A method of claim 11, further comprising
transmitting a first signal at the first frequency;
processing a first received signal in response to the first transmitted signal to determine a sustained interference;
if sustained interference is determined based upon the first received signal, transmitting a second signal at a second frequency;
processing a second received signal in response to the second transmitted signal to determine a sustained interference; and
if sustained interference is not determined in the second received signal, detecting an impedance value for the second received signal and determining an occupant based upon the impedance value.

13. A method of claim 10, wherein the interference signal is indicative of a transient interference.

14. A method of claim 13, further comprising the steps of
transmitting a series of signals;
for each signal, determining if the signal is indicative of transient interference; and
determining a sustained interference when a number of signal in the series indicating transient interference is greater than a threshold.

15. A method of claim 10, further comprising the steps of processing the first signal to determine a first impedance value, processing a second signal to determine a second impedance value, comparing the first impedance value to the second impedance value, and if a difference between the first impedance and the second impedance is below a threshold, determining an occupant based upon the first impedance value.

16. A method of claim 15, wherein the electronic device has an interference signal detection circuit and an impedance detection circuit, said method further comprising enabling the interference signal detection circuit and disabling the impedance detection circuit during a listen mode to detect transient interference, and enabling both the interference signal detection circuit and the impedance detection circuit during a receive mode.

17. A method of claim 10, further comprising the steps of enabling or disabling an airbag system of a vehicle based upon a determination of an occupant.
